(19) United States
(12) Patent Application Publication
(10) Pub. No.: US 2025/0040416 A1
(43) Pub. Date: Jan. 30, 2025

(54) DISPLAY PANEL, MANUFACTURING METHOD THEREOF, AND DISPLAY DEVICE

(71) Applicant: Hubei Yangtze Industrial Innovation Center Of Advanced Display Co., Ltd., Wuhan (CN)

(72) Inventors: Lei WANG, Wuhan (CN); Jun YAN, Wuhan (CN); You GAO, Wuhan (CN)

(21) Appl. No.: 18/916,768

(22) Filed: Oct. 16, 2024

(30) Foreign Application Priority Data
Aug. 16, 2024 (CN) 202411134860.4

(51) Int. Cl. H10K 59/80; H10K 59/12; H10K 59/122; H10K 59/173

(52) U.S. Cl. CPC H10K 59/8791; H10K 59/1201; H10K 59/122; H10K 59/173

(57) ABSTRACT

Display panel, manufacturing method thereof and display device are provided for simplifying the process of the display panel and reducing the production cost. The display panel includes: substrate; light-emitting device layer including plurality of light-emitting elements; light-shielding layer located on side of the light-emitting device layer away from the substrate. The light-shielding layer includes first openings. In direction perpendicular to plane of the substrate, the first openings overlap with the light-emitting elements; at least low refractive index layer located on side of light-shielding layer away from the substrate. The low refractive index layer includes second openings. The second openings expose the first openings; reflection adjustment layer. The reflection adjustment layer is at least located in the first openings and the second openings. The reflection adjustment layer contains dye, and the refractive index of the reflection adjustment layer is greater than the refractive index of the low refractive index layer.

### CROSS-REFERENCE TO RELATED APPLICATIONS

The present disclosure claims priority to Chinese Application No. 202411134860.4 with the application title of “DISPLAY PANEL, MANUFACTURING METHOD THEREOF, AND DISPLAY DEVICE”, filed on Aug. 16, 2024, the content of which is incorporated herein by reference in its entirety.

### TECHNICAL FIELD

The present disclosure relates to the field of display technologies, and in particular relates to a display panel, a manufacturing method thereof and a display device.

### BACKGROUND

At present, in order to optimize display performance, the display panel is also provided with a filter structure for absorbing ambient light and reducing panel reflection, and a light extraction structure for improving light extraction efficiency. However, the process of the existing filter structure and light extraction structure is complex and the production cost is high.

### SUMMARY

Embodiments of the present disclosure provide a display panel, a manufacturing method thereof and a display device for simplifying the process of the display panel and reducing the production cost.

According to a first aspect, an embodiment of the present disclosure provides a display panel, including:
a substrate;
a light-emitting device layer including a plurality of light-emitting elements;
a light-shielding layer located on a side of the light-emitting device layer away from the substrate, where the light-shielding layer includes a plurality of first openings, and in a direction perpendicular to a plane of the substrate, the first openings overlap with the light-emitting elements;
a low refractive index layer located on at least a side of the light-shielding layer away from the substrate, where the low refractive index layer includes a plurality of second openings, and the second openings exposes the first openings; and
a reflection adjustment layer located in at least the first openings and the second openings, where the reflection adjustment layer includes dye, and the refractive index of the reflection adjustment layer is greater than the refractive index of the low refractive index layer.

According to a second aspect, based on the same inventive concept, an embodiment of the present disclosure also provides a manufacturing method of a display panel, including:
forming a light-emitting device layer including a plurality of light-emitting elements on a substrate;
forming a light-shielding layer on a side of the light-emitting device layer away from the substrate, where the light-shielding layer includes a plurality of first openings, and in a direction perpendicular to a plane of the substrate, the first openings overlap with the light-emitting elements;
forming a low refractive index layer on the light-shielding layer, where the low refractive index layer includes a plurality of second openings, and the second openings expose the first openings; and
forming a reflection adjustment layer located in at least the first openings and the second openings, where the reflection adjustment layer includes dye, and the refractive index of the reflection adjustment layer is greater than the refractive index of the low refractive index layer.

According to a third aspect, based on the same inventive concept, an embodiment of the present disclosure also provides a display device including the above display panel.

The technical solution provided by the embodiments of the present disclosure has the following beneficial effects:

In the embodiments of the present disclosure, the reflection adjustment layer may achieve the functions of the color film and the high refractive index layer in the related art.

Specifically, the reflection adjustment layer and the light-shielding layer may form a filter structure. Since the wavelength range of light absorbed by the dye in the reflection adjustment layer deviates from the emission wavelength range of the light-emitting element, the light emitted by the light-emitting element may normally pass through the first opening and be emitted through the reflection adjustment layer. At the same time, after the external ambient light enters the display panel and reaches the reflection adjustment layer, part of the ambient light will be absorbed by the dye and may not be further transmitted inward, thus effectively reducing the amount of ambient light entering the interior of the display panel and thereby reducing reflection.

The reflection adjustment layer and the low refractive index layer may form a light extraction structure. Since the refractive index of the reflection adjustment layer is greater than the refractive index of the low refractive index layer, when part of the large-angle light emitted by the light-emitting element is transmitted to the side wall of the second opening, refraction will occur at the interface between the reflection adjustment layer and the low refractive index layer. The transmission direction of the refracted light is closer to the normal viewing angle direction, thereby realizing the conversion of large-angle light into small-angle light and improving the light extraction efficiency of the light-emitting element.

In summary, by adopting the technical solutions provided by the embodiments of the present disclosure, the color film and the high refractive index layer in the related art may be replaced by only one film layer of the reflection adjustment layer, which greatly simplifies the process of the filter structure and the light extraction structure. First, the masking process of the high refractive index layer may be omitted. Second, since the reflection adjustment layer may absorb light in other wavelength bands except the red, green, and blue light bands, there is no need to design filter film layers of different materials for different color light-emitting elements. At most, only one masking process is required for the reflection adjustment layer. Compared with the original color film process, at least two masking processes may be saved. Therefore, by adopting the structure provided by the embodiments of the present disclosure, at least three masking processes may be saved in the process of the filter structure and the light extraction structure, thereby greatly simplifying the process and reducing the production cost of the display panel.

In addition, the reflection adjustment layer is reused as two film layers of the color film and the high refractive index layer, which may also eliminate the influence of the color film and the high refractive index layer on light due to the difference in refractive index, thereby achieving more accurate control of light transmission.

### BRIEF DESCRIPTION OF DRAWINGS

In order to more clearly illustrate the technical solutions in the embodiments of the present disclosure or the related art, the following will briefly introduce the drawings required for the description of the embodiments or the related art. Obviously, the drawings described below are some embodiments of the present disclosure. For those skilled in the art, other drawings may be obtained based on these drawings without creative efforts.

FIG. 1 is a schematic structural diagram of a display panel in the related art;

FIG. 2 is a schematic structural diagram of a display panel according to an embodiment of the present disclosure;

FIG. 3 is a schematic diagram of light transmission according to an embodiment of the present disclosure;

FIG. 4 is a top view of a display panel according to an embodiment of the present disclosure;

FIG. 5 is a cross-sectional view along the A1-A2 direction of FIG. 4;

FIG. 6 is another schematic structural diagram of a display panel according to an embodiment of the present disclosure;

FIG. 7 is another top view of a display panel according to an embodiment of the present disclosure;

FIG. 8 is a cross-sectional view along the B1-B2 direction of FIG. 7;

FIG. 9 is another top view of a display panel according to an embodiment of the present disclosure;

FIG. 10 is a cross-sectional view along the C1-C2 direction of FIG. 9;

FIG. 11 is another schematic structural diagram of a display panel according to an embodiment of the present disclosure;

FIG. 12 is another schematic structural diagram of a display panel according to an embodiment of the present disclosure;

FIG. 13 is another schematic structural diagram of a display panel according to an embodiment of the present disclosure;

FIG. 14 is another schematic structural diagram of a display panel according to an embodiment of the present disclosure;

FIG. 15 is another schematic diagram of light transmission according to an embodiment of the present disclosure;

FIG. 16 is another schematic structural diagram of a display panel according to an embodiment of the present disclosure;

FIG. 17 is a structural flowchart of a manufacturing method of a display panel according to an embodiment of the present disclosure;

FIG. 18 is another structural flowchart of a manufacturing method of a display panel according to an embodiment of the present disclosure;

FIG. 19 is another structural flowchart of a manufacturing method of a display panel according to an embodiment of the present disclosure; and

FIG. 20 is a schematic structural diagram of a display device according to an embodiment of the present disclosure.

### DESCRIPTION OF EMBODIMENTS

To better understand the technical solution of the present disclosure, the following will provide a detailed description of the embodiments of the present disclosure in conjunction with the drawings.

It should be clear that the described embodiments are only some embodiments of the present disclosure, not all embodiments. Based on the embodiments in the present disclosure, all other embodiments obtained by those of ordinary skill in the art without creative efforts fall within the protection scope of the present disclosure.

The terms used in the embodiments of the present disclosure are only for the purpose of describing specific embodiments and are not intended to limit the present disclosure. The singular forms “a/an”, “the” and “said” used in the embodiments of the present disclosure and the appended claims are also intended to include the plural forms unless the context clearly indicates otherwise.

It should be understood that the term “and/or” used herein is only an association relationship for describing associated objects, indicating that there may be three relationships. For example, A and/or B may mean: A exists alone, A and B exist simultaneously, and B exists alone. In addition, the character “/” in the application generally indicates that the associated objects are in an “or” relationship.

Before elaborating on the technical solutions provided by the embodiments of the present disclosure, the present disclosure first introduces the structures of the filter layer and the light-extracting layer in the related art.

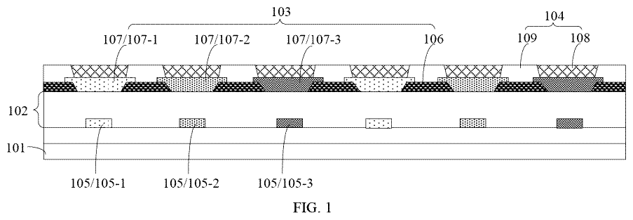

As shown in FIG. 1, which is a schematic structural diagram of a display panel in the related art, the display panel includes a substrate 101, a light-emitting device layer 102, a filter layer 103 and a light-extracting layer 104.

In one embodiment, the light-emitting device layer 102 includes a plurality of light-emitting elements 105.

The filter layer 103 includes a light-shielding layer 106 and a plurality of color films 107. There are a plurality of openings in the black matrix, and at least part of the plurality of color films 107 are located in the openings. The plurality of color films 107 overlap with the plurality of light-emitting elements 105 respectively. The color film 107 is used to transmit the light of the color emitted by the overlapping of the plurality of light-emitting elements 105 and absorb light of other colors, thereby reducing the ambient light entering the display panel and reducing panel reflection.

The light-extracting layer 104 includes a high refractive index layer 108 and a low refractive index layer 109. By using the refraction effect of the high refractive index layer 108 and the low refractive index layer 109 on light, part of the large-angle light emitted by the light-emitting element 105 is converted into small-angle light, thereby improving the light extraction efficiency of the light-emitting element 105.

It should be further noted that since the display panel is usually provided with multiple colors of light-emitting elements 105, correspondingly, the filter layer 103 is also required to provide with multiple types of color films 107. For example, the plurality of light-emitting elements 105 include a red light-emitting element 105-1, a green light-emitting element 105-2 and a blue light-emitting element 105-3. The plurality of color films 107 include a first color film 107-1 overlapping with the red light-emitting element 105-1, a second color film 107-2 overlapping with the green light-emitting element 105-2 and a third color film 107-3 overlapping with the blue light-emitting element 105-3. Since the materials of the first color film 107-1, the second color film 107-2 and the third color film 107-3 are different, these three types of color films need to be formed by three masking processes respectively.

In the process of forming the filter layer 103 and the light-extracting layer 104, at least six masking processes are needed: one of them is used to form the light-shielding layer 106, three of them are used to form the first color film 107-1, the second color film 107-2 and the third color film 107-3 respectively, and two of them are used to form the high refractive index layer 108 and the low refractive index layer 109 respectively. This leads to a cumbersome process and high production costs.

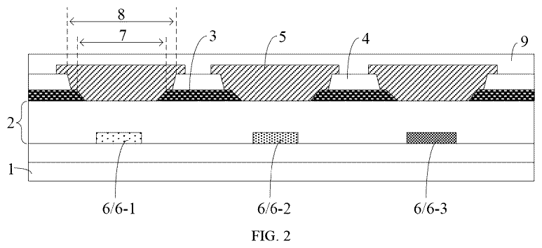

In this regard, an embodiment of the present disclosure provides a display panel. As shown in FIG. 2, which is a schematic structural diagram of a display panel provided by an embodiment of the present disclosure, the display panel includes a substrate 1, a light-emitting device layer 2, a light-shielding layer 3, a low refractive index layer 4 and a reflection adjustment layer 5.

In one embodiment, the light-emitting device layer 2 includes a plurality of light-emitting elements 6. The light-emitting elements 6 may be devices of types such as Organic Light Emitting Diode (OLED), Light Emitting Diode (LED).

The light-shielding layer 3 is located on a side of the light-emitting device layer 2 away from the substrate 1. The light-shielding layer 3 includes a plurality of first openings 7. In a direction perpendicular to the plane where the substrate 1 is located, the plurality of plurality of first openings 7 overlap with the light-emitting elements 6.

The low refractive index layer 4 is at least located on a side of the light-shielding layer 3 away from the substrate 1. The low refractive index layer 4 includes a plurality of second openings 8. The plurality of second openings 8 expose the plurality of plurality of first openings 7.

The reflection adjustment layer 5 is at least located in the plurality of plurality of first openings 7 and the plurality of second openings 8. The reflection adjustment layer 5 contains dye, and the refractive index of the reflection adjustment layer 5 is greater than that of the low refractive index layer 4.

The dye is used to absorb light within a certain wavelength range, and the wavelength range of light absorbed by the dye deviates from the emission wavelength range of the light-emitting element 6. For example, the plurality of light-emitting elements 6 include a red light-emitting element 6-1, a green light-emitting element 6-2 and a blue light-emitting element 6-3. The wavelength range of light absorbed by the dye simultaneously deviates from the wavelength range of red light emitted by the red light-emitting element 6-1, the wavelength range of green light emitted by the green light-emitting element 6-2 and the wavelength range of blue light emitted by the blue light-emitting element 6-3. In one embodiment, the dye may absorb light in the 480 nm to 500 nm band and/or absorb light in the 585 nm to 605 nm band.

In the embodiments of the present disclosure, the reflection adjustment layer 5 may include dye, or may include dye and pigments. For example, the reflection adjustment layer 5 may include compounds based on tetraazaporphyrin (TAP), compounds based on porphyrin, compounds based on metal porphyrin, compounds based on oxazine, compounds based on squaraine, compounds based on triarylmethane, compounds based on polymethine, compounds based on tetraquinone, compounds based on phthalocyanine, compounds based on azo, compounds based on perylene, compounds based on xanthene, compounds based on diimonium, compounds based on dipyrromethene, or compounds based on cyanine and combinations thereof.

In the above structure, the reflection adjustment layer 5 may achieve the functions of the color film and the high refractive index layer in the related art.

Specifically, the reflection adjustment layer 5 and the light-shielding layer 3 may form a filter structure. Since the wavelength range of light absorbed by the dye in the reflection adjustment layer 5 deviates from the emission wavelength range of the light-emitting element 6, the light emitted by the light-emitting element 6 may normally pass through the first opening 7 and be emitted through the reflection adjustment layer 5. At the same time, after the external ambient light enters the display panel and reaches the reflection adjustment layer 5, part of the ambient light will be absorbed by the dye and may not be further transmitted inward, thus effectively reducing the amount of ambient light entering the interior of the display panel and thereby reducing reflection.

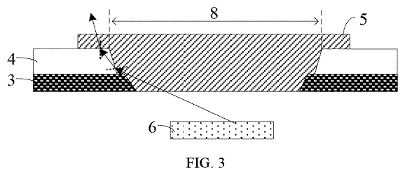

The reflection adjustment layer 5 and the low refractive index layer 4 may form a light extraction structure. Since the refractive index of the reflection adjustment layer 5 is greater than that of the low refractive index layer 4. Therefore, combined with FIG. 3, which is a schematic diagram of light transmission provided by an embodiment of the present disclosure, when part of the large-angle light emitted by the light-emitting element 6 is transmitted to the side wall of the second opening 8, it will be refracted at the interface between the reflection adjustment layer 5 and the low refractive index layer 4. The transmission direction of the refracted light is closer to the normal viewing angle direction, thereby realizing the conversion of large-angle light into small-angle light and improving the light extraction efficiency of the light-emitting element 6.

In summary, by adopting the technical solutions provided by the embodiments of the present disclosure, the color film and the high refractive index layer in the related art may be replaced by only one film layer of the reflection adjustment layer 5, thereby greatly simplifying the process of the filter structure and the light extraction structure. First, the masking process of the high refractive index layer may be omitted. Second, since the reflection adjustment layer 5 may absorb light in other wavelength bands except the red, green, and blue light bands, there is no need to design filter film layers of different materials for different color light-emitting elements 6. At most, only one masking process is required for the reflection adjustment layer 5. Compared with the original color film process, at least two masking processes may be saved. Therefore, in the process of the filter structure and the light extraction structure, the embodiments of the present disclosure may save at least three masking processes, thereby greatly simplifying the process and reducing the production cost of the display panel.

In addition, replacing the two film layers of the color film and the high refractive index layer with only one film layer of the reflection adjustment layer 5 may also eliminate the influence of the color film and the high refractive index layer on the transmission of light due to the difference in refractive index, thereby achieving more accurate control of the transmission of light.

In a feasible implementation manner, referring again to FIG. 2, the reflection adjustment layer 5 also covers at least part of the low refractive index layer 4.

That is, the reflection adjustment layer 5 also at least covers partially on the side of the low refractive index layer 4 away from the substrate 1, which may increase the area of the interface between the reflection adjustment layer 5 and the low refractive index layer 4. Combined with FIG. 3, after the large-angle light emitted by the light-emitting element 6 is refracted at the side wall of the second opening 8, part of the refracted light will be further transmitted above to the interface between the low refractive index layer 4 and the reflection adjustment layer 5, and then refraction occurs again at this interface, resulting in a smaller transmission angle of the refracted light, which is more likely to be emitted in the direction of the normal viewing angle, thereby improving the brightness of the normal viewing angle to a greater extent.

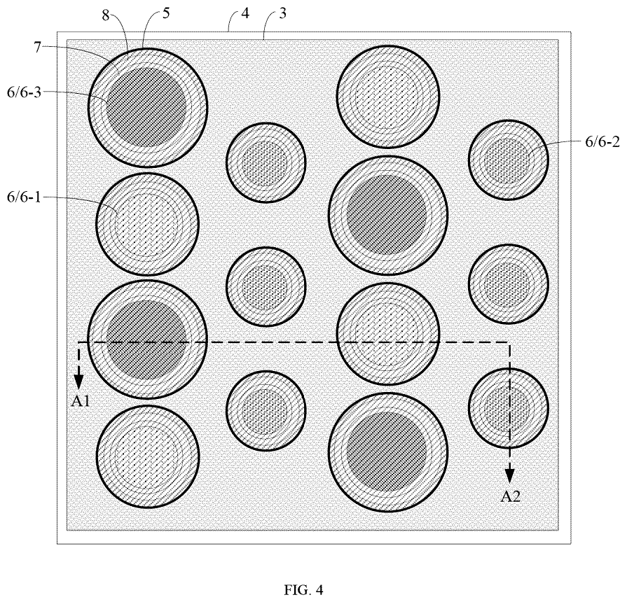

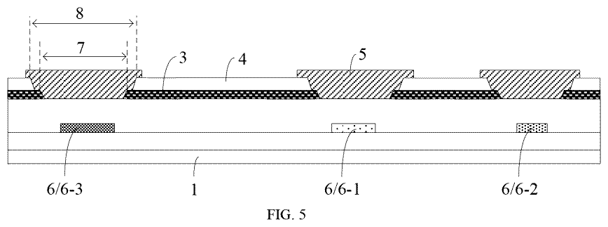

In a feasible implementation manner, as shown in FIGS. 4 and 5, which are a top view of a display panel provided by an embodiment of the present disclosure and a cross-sectional view along the A1-A2 direction of FIG. 4, the display panel includes a plurality of independent reflection adjustment layers 5. In a direction perpendicular to the plane where the substrate 1 is located, one reflection adjustment layer 5 at least overlaps with one light-emitting element 6. That is, the reflection adjustment layer 5 adopts an island design. The embodiment of the present disclosure is illustrated by taking one reflection adjustment layer 5 overlapping with one light-emitting element 6 as an example.

Referring again to FIG. 2, an optical adhesive layer 9 is usually provided above the reflection adjustment layer 5. The island design of the reflection adjustment layer 5 may reduce the contact area between the reflection adjustment layer 5 and the optical adhesive layer 9, thereby reducing the risk of the dye in the reflection adjustment layer 5 migrating to the optical adhesive layer 9, and keeping the reflection adjustment layer 5 with better anti-reflection characteristics.

Further, referring again to FIGS. 4 and 5, when the reflection adjustment layer 5 is in an island design, part of the reflection adjustment layer 5 is also located on the side of the low refractive index layer 4 away from the substrate 1. That is, the edge of the reflection adjustment layer 5 should extend outward from the edge of the second opening 8. This may leave an error space for the arrangement positions of the reflection adjustment layer 5 and the second opening 8. Even if the actual positions of the reflection adjustment layer 5 and/or the second opening 8 are shifted due to factors such as process errors, the second opening 8 may still be completely filled with the reflection adjustment layer 5 to ensure the dimming effect. In addition, based on the aforementioned analysis, the reflection adjustment layer 5 is also located on the side of the low refractive index layer 4 away from the substrate 1, which may also make the light refract multiple times, helping to further reduce the light-emitting angle and improve the brightness of light emitted from the normal viewing angle.

In a feasible implementation manner, referring again to FIG. 4, the overlapping light-emitting element 6, the first opening 7, the second opening 8 and the reflection adjustment layer 5 have the same shape.

The shape matching of these structures may make the light shielding layer 3, the reflection adjustment layer 5, and the low refractive index layer 4 have consistent regulation of the light emitted by the light emitting element 6 in different orientations, resulting in better light output effects. In one embodiment, in order to improve the diffraction phenomenon, the light-emitting element 6 may be designed as a circular or quasi-circular shape. Correspondingly, the first opening 7, the second opening 8 and the reflection adjustment layer 5 are also circular or quasi-circular.

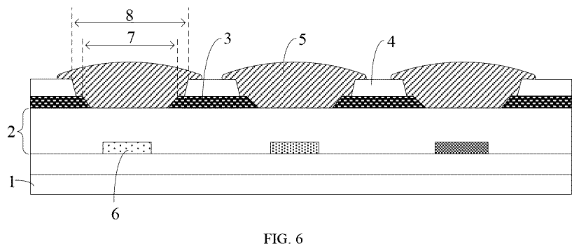

In a feasible implementation manner, as shown in FIG. 6, which is another schematic structural diagram of a display panel provided by an embodiment of the present disclosure, the surface of the reflection adjustment layer 5 far away from the substrate 1 is arched towards a direction away from the substrate 1.

The reflection adjustment layer 5 of this structure may be specifically formed by inkjet printing process. After the low refractive index layer 4 is formed, the material for forming the reflection adjustment layer 5 is sprayed to the printing area by using a nozzle. Under the action of surface tension, the upper surface of the ejected material will appear to arc, so that the upper surface of the finally formed reflection adjustment layer 5 is arched towards the direction away from the substrate 1.

Since the inkjet printing may be used to directly form the reflection adjustment layer 5 with a specific pattern and without using a mask, one more masking process may be omitted, so that only two masking processes are used in the process of the filter structure and the light extraction structure, which saves four masking processes and reduces the production cost of the display panel to a greater extent.

In a feasible implementation manner, referring again to FIG. 2, the surface of the reflection adjustment layer 5 far away from the substrate 1 is a flat surface. That is, the distances between the surface of the reflection adjustment layer 5 far away from the substrate 1 and the substrate 1 at different positions are equal.

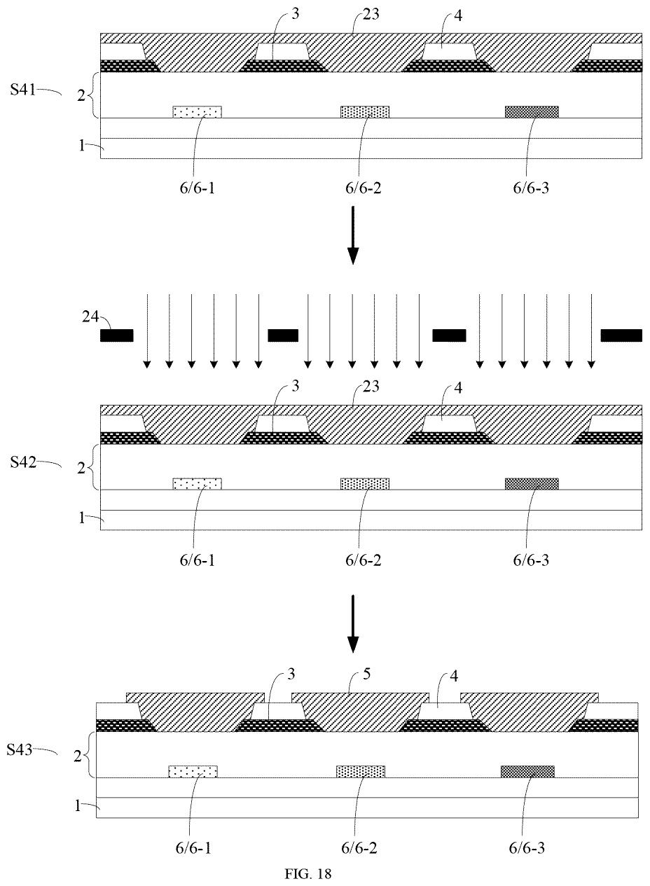

In reference to FIG. 18, the reflection adjustment layer 5 with this structure may be specifically formed by a photolithography process. After the low refractive index layer 4 is formed, a full layer of the film layer 23 to be processed is first coated. The material of the film layer 23 to be processed may be resin composition materials including dye, resin, and photoinitiators. Then, the film layer 23 to be processed is patterned using exposure and development to form a reflection adjustment layer 5 with a specific pattern.

It is to be understood that some small molecule monomers will also be free in the materials of the coated film layer 23 to be processed. Ultraviolet light irradiation is required in the exposure process. During this process, due to the action of the photoinitiators, some monomers in the materials may crosslink with the resin, making the materials denser and limiting the movement of the dye, reducing the risk of dye migration to the optical adhesive layer 9.

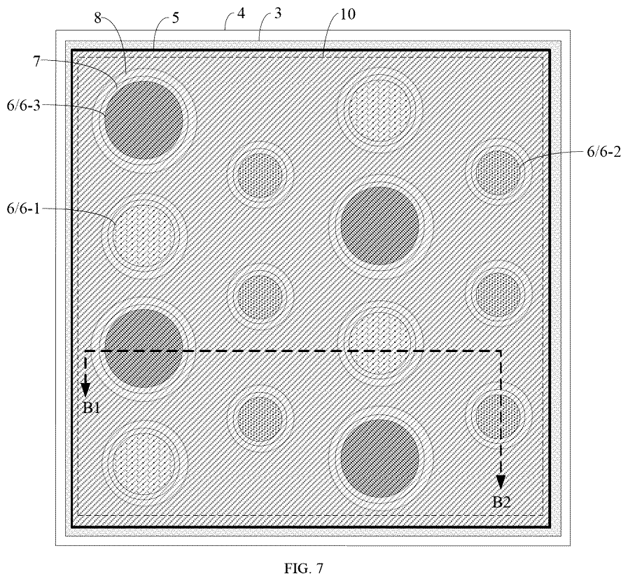

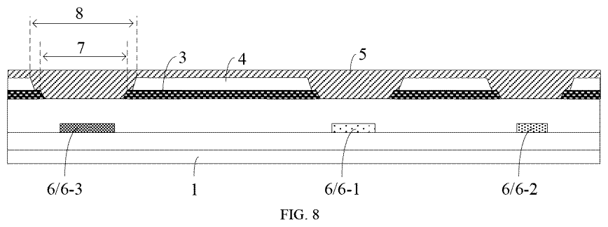

In a feasible implementation manner, as shown in FIGS. 7 and 8, which are another top view of a display panel provided by an embodiment of the present disclosure and a cross-sectional view along the B1-B2 direction of FIG. 7, the display panel includes a display area 10. The reflection adjustment layer 5 at least covers the display area 10. At this time, the reflection adjustment layer 5 has a larger coverage area and may absorb more ambient light to further reduce panel reflection.

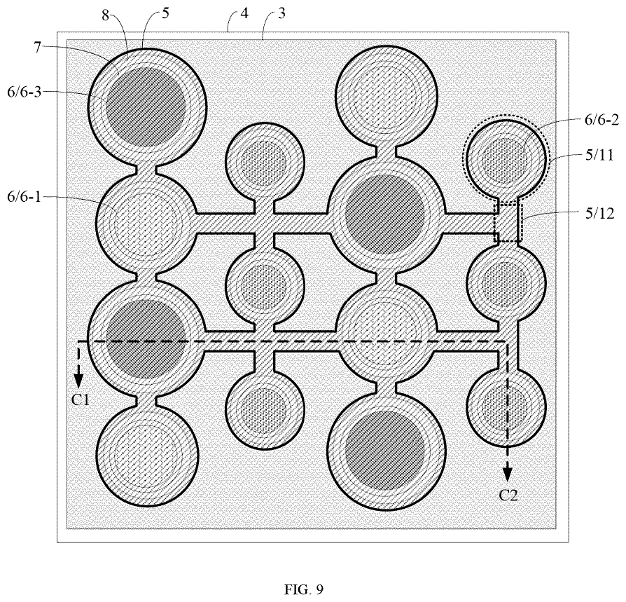

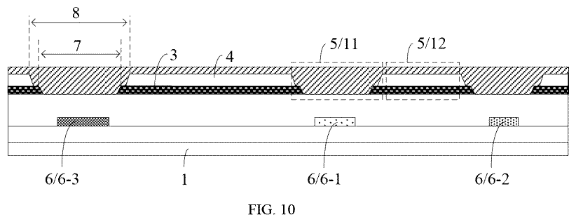

In a feasible implementation manner, as shown in FIGS. 9 and 10, which are another top view of a display panel provided by an embodiment of the present disclosure, and a cross-sectional view along the C1-C2 direction of FIG. 9, the reflection adjustment layer 5 includes a first sub-part 11 and a second sub-part 12. In one embodiment, the first sub-part 11 is located in the first opening 7 and the second opening 8. The second sub-part 12 is connected between different first sub-parts 11. In other words, the reflection adjustment layer 5 is provided with hollows, and the positions of the hollows avoid the positions of the light-emitting elements 6.

The reflection adjustment layer 5 with this structure may not only increase the coverage area of the reflection adjustment layer 5 to some extent by using the second sub-part 12, allowing it to absorb more ambient light, but also avoid excessive coverage area of the reflection adjustment layer 5 by using the hollows, thereby preventing more dye from migrating into the optical adhesive layer 9.

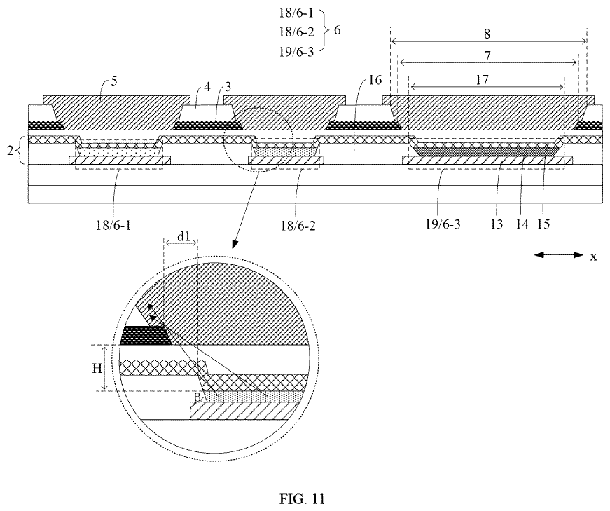

In a feasible implementation manner, as shown in FIG. 11, which is another schematic structural diagram of a display panel provided by an embodiment of the present disclosure, the light-emitting element 6 includes an anode 13, a light-emitting layer 14 and a cathode 15.

The light-emitting device layer 2 also includes a pixel definition layer 16. The pixel definition layer 16 includes a fourth opening 17. The light-emitting layer 14 is located in the fourth opening 17. In a direction perpendicular to the plane where the substrate 1 is located, the fourth opening 17 is located in the corresponding first opening 7, and there is a gap between the edge of the fourth opening 17 and the edge of the first opening 7.

Moreover, for the overlapping first opening 7 and fourth opening 17, along the first direction x, the distance d1 between the edge of the first opening 7 and the edge of the fourth opening 17 is greater than or equal to H×Ctgβ. The first direction x is parallel to the plane where the substrate 1 is located, H is the distance between the light-shielding layer 3 and the light-emitting layer 14 along a second direction. The second direction is perpendicular to the plane where the substrate 1 is located, β is the first included angle of the fourth opening 17. The first included angle is the angle between the side wall of the fourth opening 17 and the surface connected to it and close to the substrate 1, that is, the taper angle of the pixel definition layer 16.

When the distance d1 by the first opening 7 extending outward from the fourth opening 17 meets the above conditions, more light emitted by the light-emitting element 6 may pass through the first opening 7 and be emitted towards the side wall of the second opening 8, and then more light may be refracted at the interface between the reflection adjustment layer 5 and the low refractive index layer 4.

Further, referring again to FIG. 11, the light-emitting elements 6 include a first light-emitting element 18 and a second light-emitting element 19. The first light-emitting element 18 and the second light-emitting element 19 are used to emit light of different colors.

In one embodiment, the first included angle β of the fourth opening 17 corresponding to the first light-emitting element 18 is different from the first included angle 3 of the fourth opening 17 corresponding to the second light-emitting element 19. Then correspondingly, the distance d1 corresponding to the first light-emitting element 18 and the distance d1 corresponding to the second light-emitting element 19 are also different. The amount of light emitted by the two light-emitting elements 6 that may be regulated is different. Thus, according to the light-emitting requirements of the different color light-emitting elements 6, the light-emitting efficiency of two different color light-emitting elements 6 may be regulated more flexibly.

In one setting manner, the first light-emitting element 18 includes a red light-emitting element 6-1 and a green light-emitting element 6-2. The first included angles β of the fourth opening 17 corresponding to the red light-emitting element 6-1 and the green light-emitting element 6-2 are 45°. The second light-emitting element 19 includes a blue light-emitting element 6-3. The first included angle β of the fourth opening 17 corresponding to the blue light-emitting element 6-3 is 35°.

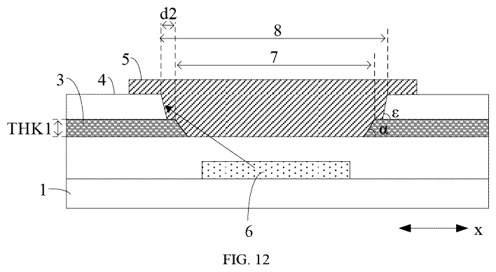

In a feasible implementation manner, as shown in FIG. 12, which is another schematic structural diagram of a display panel provided by an embodiment of the present disclosure. In a direction perpendicular to the plane where the substrate 1 is located, the first opening 7 is located in the second opening 8. Moreover, along the first direction x, there is a gap between the edge of the second opening 8 and the edge of the first opening 7. The first direction x is parallel to the plane where the substrate 1 is located.

The second opening 8 extends outward from the first opening 7. Only the large-angle light emitted by the light-emitting element 6 will be transmitted to the interface between the reflection adjustment layer 5 and the low refractive index layer 4 and be converted into small-angle light. The small-angle light emitted by the light-emitting element 6 may be emitted normally along the original path, thereby realizing targeted regulation of large-angle light.

Further, referring again to FIG. 12, for the corresponding first opening 7 and second opening 8, along the first direction x, the distance d2 between the edge of the second opening 8 and the edge of the first opening 7 is less than or equal to THK1×Ctgα. THK1 is the thickness of the light-shielding layer 3 in the direction perpendicular to the plane where the substrate 1 is located; a is the angle between the side wall of the first opening 7 and the surface connected to it and close to the side of the substrate 1, that is, the taper angle of the light-shielding layer 3.

With this setting, it may be avoided that the second opening 8 extends too much from the first opening 7, resulting in part of the large-angle light being unable to be transmitted to the interface between the reflection adjustment layer 5 and the low refractive index layer 4.

In a feasible implementation manner, referring again to FIG. 12, the angle between the side wall of the first opening 7 and the surface connected to it and close to the side of the substrate 1 is α, that is, the taper angle of the light-shielding layer 3 is α. The angle between the side wall of the second opening 8 and the surface connected to it and close to the side of the substrate 1 is ε, that is, the taper angle of the low refractive index layer 4 is ε. In order to enable more large-angle light to be transmitted to the interface between the reflection adjustment layer 5 and the low refractive index layer 4 and be refracted, α may be designed to be less than or equal to ε, that is, to make the taper angle of the low refractive index layer 4 larger.

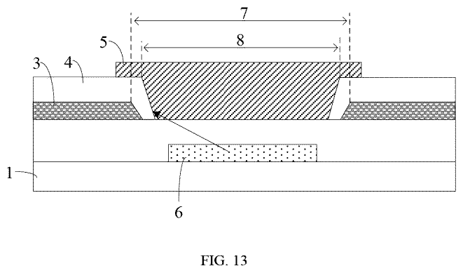

In a feasible implementation manner, as shown in FIG. 13, which is another schematic structural diagram of a display panel provided by an embodiment of the present disclosure, the low refractive index layer 4 is also located on the side wall of the first opening 7, that is, the first opening 7 may also extend outward from the second opening 8.

The difference between this structure and the related structure is as follows: in the related structure shown in FIG. 1, the high refractive index layer 108 may only be formed after the color film 107 is formed. Therefore, the high refractive index layer 108 may not be located on the side wall of the opening of the light-shielding layer 106. In the structure provided by the embodiments of the present disclosure, after the reflection adjustment layer 5 replaces the color film and the high refractive index layer, the reflection adjustment layer 5 may be located on the side wall of the opening of the light-shielding layer 3 by increasing the size of the first opening 7. That is, the position design of the reflection adjustment layer 5 in the present disclosure will be more flexible.

When the reflection adjustment layer 5 is located on the side wall of the opening of the light-shielding layer 3, some light that originally was incident towards the light-shielding layer 3 and was absorbed by the light-shielding layer 3 may be refracted at the interface between the reflection adjustment layer 5 and the low refractive index layer 4 before being incident on the light-shielding layer 3, and finally be directed out of the display panel, thereby improving the light extraction efficiency.

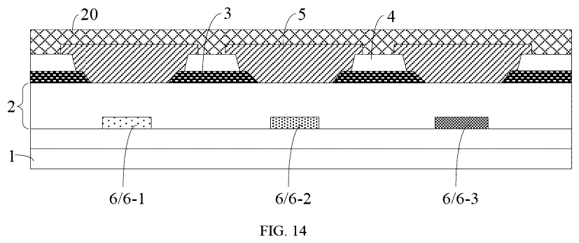

In a feasible implementation manner, as shown in FIG. 14, which is another schematic structural diagram of a display panel provided by an embodiment of the present disclosure, the display panel also includes a high refractive index layer 20. The high refractive index layer 20 is located on the side of the reflection adjustment layer 5 away from the substrate 1 and covers the low refractive index layer 4. The refractive index of the high refractive index layer 20 is greater than that of the reflection adjustment layer 5.

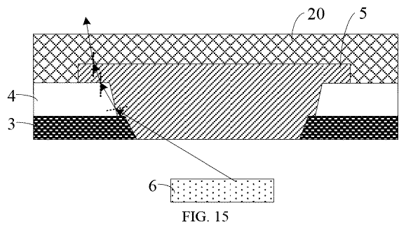

As shown in FIG. 15, which is another schematic diagram of light transmission provided by an embodiment of the present disclosure, after the light is transmitted to the upper surface of the reflection adjustment layer 5, it will be further refracted at the interface between the reflection adjustment layer 5 and the high refractive index layer 20, thereby readjusting the transmission direction of the light, so that more light will be directed out of the panel in a direction closer to the normal viewing angle direction.

In addition, it should be noted that since the use of the reflection adjustment layer 5 may save at least three masking processes compared to related technologies. Therefore, even if an additional masking process is used to form the above-mentioned high refractive index layer 20, compared to related technologies, the total number of masking processes used in the present disclosure is also reduced. In other words, the embodiments of the present disclosure may use the masking processes saved by the reflection adjustment layer 5 to form some other film layers so that the display panel may achieve better characteristics.

In a feasible implementation manner, the reflection adjustment layer 5 also includes high refractive index resin materials, so that the high refractive index resin materials are directly used to form the reflection adjustment layer 5 with a relatively high refractive index, thereby realizing its high refractive performance. Exemplarily, the high refractive index resin materials may include polystyrene resin, polycarbonate resin, cycloolefin polymer, and the like.

In a feasible implementation manner, the reflection adjustment layer 5 also includes resin materials and high refractive index particles, so that the high refractive index particles are used to form the reflection adjustment layer 5 with a relatively high refractive index, thereby realizing its high refractive performance. This structure has less restriction on the refractive index of the resin materials used, and the optional range of the resin materials is relatively large.

Further, in the reflection adjustment layer 5, at least a part of the high refractive index particles are grafted with resin.

In the specific process of grafting the high refractive index particles with the resin, first, the surface of the high refractive index particles is treated so that the surface of the high refractive index particles has functional groups that may react with the resin. Then, the treated high refractive index particles, the dye, the photoinitiators and the resin are mixed and placed at least in the first opening 7 and the second opening 8. Then, the resin is irradiated with ultraviolet light to make the functional groups on the surface of the high refractive index particles react with the resin by grafting, thereby realizing the grafting of the high refractive index particles and the resin.

Exemplarily, when the reflection adjustment layer 5 is formed by a photolithography process, more specifically, first, the surface of the high refractive index particles is treated so that the surface of the high refractive index particles has functional groups that may react with the resin. Then, the treated high refractive index particles, the dye, the photoinitiators and the resin are mixed to form resin composition materials, and the resin composition materials are coated on the low refractive index layer 4. Then, the resin composition materials are patterned by an exposure and development process to form the reflection adjustment layer 5. During the exposure process, ultraviolet light irradiates the resin composition materials, which will cause the functional groups on the surface of the high refractive index particles to react with the resin by grafting, thereby realizing the grafting of the high refractive index particles and the resin.

The grafting of the high refractive index particles and the resin may restrain the high refractive index particles so that they will not migrate to other film layers. For example, they will not migrate to the optical adhesive layer 9 above the reflection adjustment layer 5, thereby making the high refractive property of the reflection adjustment layer 5 more stable.

In a feasible implementation manner, the high refractive index particles may include at least one of titanium oxide, zirconium oxide, hafnium oxide, tantalum oxide, tungsten oxide, niobium oxide, cerium oxide, lead oxide and zinc oxide. The resin may include at least one of acrylic resin, epoxy resin and polyurethane resin.

In one example, the high refractive index particles include zirconium dioxide, the resin includes acrylic resin, and at least part of the zirconium dioxide is grafted with the acrylic resin.

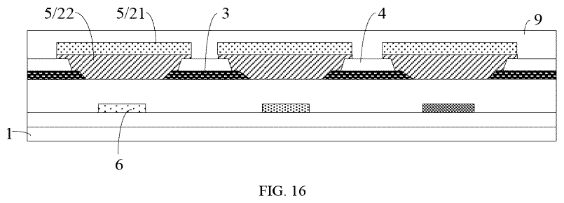

In a feasible implementation manner, as shown in FIG. 16, which is another schematic structural diagram of a display panel provided by an embodiment of the present disclosure, the reflection adjustment layer 5 includes a first sub-adjustment layer 21 and a second sub-adjustment layer 22. The first sub-adjustment layer 21 is located on the side of the second sub-adjustment layer 22 away from the substrate 1. The grafting rate of the first sub-adjustment layer 21 is greater than that of the second sub-adjustment layer 22.

In the embodiments of the present disclosure, different treatments may be performed on the high refractive index particles in the first sub-adjustment layer 21 and the second sub-adjustment layer 22 to make the high refractive index particles in the first sub-adjustment layer 21 more likely to be grafted with the resin, thereby increasing the grafting rate of the first sub-adjustment layer 21. Or, different degrees of ultraviolet light irradiation may also be performed on the first sub-adjustment layer 21 and the second sub-adjustment layer 22, thereby increasing the reaction degree of the high refractive index particles in the first sub-adjustment layer 21 with the resin, so that more high refractive index particles in the first sub-adjustment layer 21 are more likely to be grafted with the resin.

In the above structure, on the one hand, the grafting rate of the first sub-adjustment layer 21 is relatively large, that is, more high refractive index particles are grafted with the resin. This may make the materials of the first sub-adjustment layer 21 relatively dense and play a certain restrictive role on the dye migration. On the other hand, more high refractive index particles in the first sub-adjustment layer 21 are bound by the resin, which may also reduce the precipitation of high refractive index particles.

In a feasible implementation manner, referring to FIG. 16, the reflection adjustment layer 5 includes a first sub-adjustment layer 21 and a second sub-adjustment layer 22. The first sub-adjustment layer 21 is located on the side of the second sub-adjustment layer 22 away from the substrate 1. In the embodiment of the present disclosure, the first sub-adjustment layer 21 and the second sub-adjustment layer 22 may have different curing rates to optimize the characteristics of the reflection adjustment layer 5 in a certain aspect.

For example, in an optional implementation manner, the curing rate of the first sub-adjustment layer 21 may be greater than that of the second sub-adjustment layer 22. In this way, the upper half of the reflection adjustment layer 5 has a greater degree of curing, a greater degree of cross-linking between resin and monomers, and a higher material density, which may play a greater interception role on dye migration. At this time, the anti-reflection performance of the reflection adjustment layer 5 is better.

Alternatively, in another feasible implementation manner, the curing rate of the first sub-adjustment layer 21 may be less than that of the second sub-adjustment layer 22. In this way, the upper half of the reflection adjustment layer 5 has a lower degree of curing, a smaller degree of cross-linking between resin and monomers, and more unsaturated bonds in the resin. Then the resin may be grafted with more high refractive index particles, so that the high refractive index particles are not easy to precipitate. At this time, the high refractive performance of the reflection adjustment layer 5 is better.

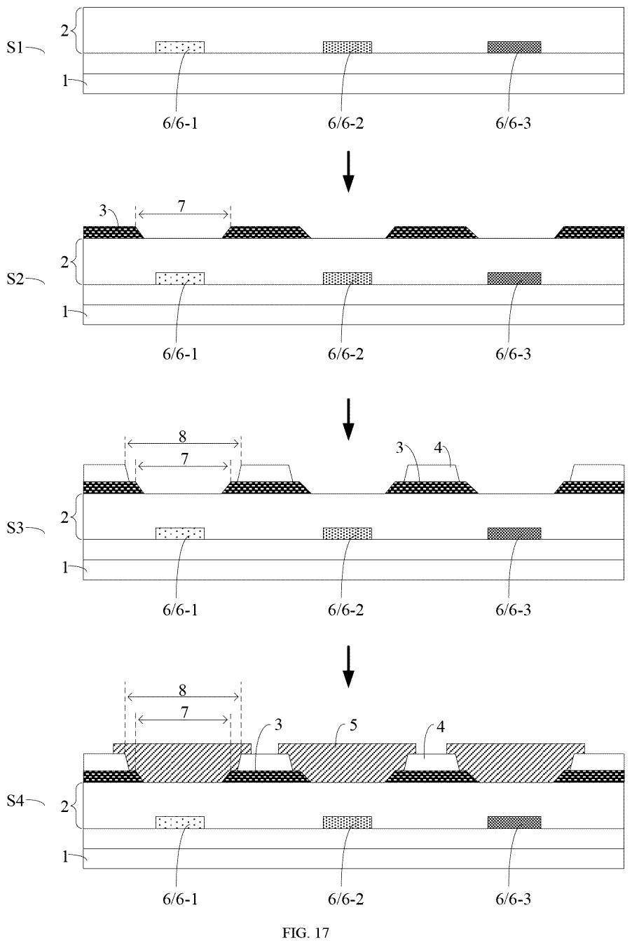

Based on the same inventive concept, an embodiment of the present disclosure also provides a manufacturing method of a display panel. As shown in FIG. 17, which is a structural flowchart of a manufacturing method of a display panel provided by an embodiment of the present disclosure, the manufacturing method includes:

Step S1: forming a light-emitting device layer 2 including a plurality of light-emitting elements 6 on the substrate 1.

Step S2: forming a light-shielding layer 3 on a side of the light-emitting device layer 2 away from the substrate 1. Where the light-shielding layer 3 includes a plurality of first openings 7. In a direction perpendicular to the plane where the substrate 1 is located, the plurality of plurality of first openings 7 overlap with the light-emitting elements 6.

Step S3: forming a low refractive index layer 4 on the light-shielding layer 3. Where the low refractive index layer 4 includes a plurality of second openings 8. The plurality of second openings 8 expose the first openings 7.

Step S4: forming a reflection adjustment layer 5. The reflection adjustment layer 5 is at least located in the first openings 7 and the plurality of second openings 8. Where the reflection adjustment layer 5 contains dye, and the refractive index of the reflection adjustment layer 5 is greater than that of the low refractive index layer 4.

Based on the foregoing analysis, it may be seen that, in the embodiments of the present disclosure, the reflection adjustment layer 5 and the light-shielding layer 3 may form a filter structure, and the reflection adjustment layer 5 and the low refractive index layer 4 may form a light extraction structure. Thus, the color film and the high refractive index layer in the related art may be replaced by only one film layer of the reflection adjustment layer 5. Compared with the process of forming the filter structure and the light extraction structure in the related art, the manufacturing method provided by the embodiment of the present disclosure may save at least three masking processes, thereby greatly simplifying the process and reducing the production cost of the display panel.

In a feasible implementation manner, the process of forming the reflection adjustment layer 5 may include: forming the reflection adjustment layer 5 by using a photolithography process.

More specifically, after the low refractive index layer 4 is formed, as shown in FIG. 18, which is another structural flowchart of the manufacturing method of the display panel provided by an embodiment of the present disclosure, first, in step S41, coating a full layer of the film layer 23 to be processed. The materials of the film layer 23 to be processed may be resin composition materials including dye, resin, and photoinitiators; then, in step S42, placing a mask 24 above the film layer 23 to be processed, and using ultraviolet light to irradiate and expose the film layer 23 to be processed; finally, in step S43, developing the film layer 23 to be processed to form the reflection adjustment layer 5.

When the reflection adjustment layer 5 is formed by a photolithography process, ultraviolet light irradiation is needed in the exposure process. In this process, under the action of the photoinitiators, some monomers in the materials may crosslink with the resin, which may improve the density of the material and improve the dye migration problem.

Alternatively, in another feasible implementation manner, the process of forming the reflection adjustment layer 5 may also include: forming the reflection adjustment layer 5 by using an inkjet printing process.

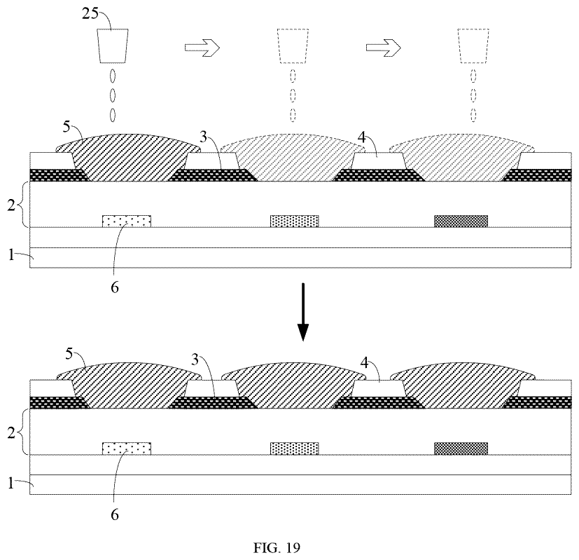

Exemplarily, after the low refractive index layer 4 is formed, as shown in FIG. 19, which is another structural flowchart of the manufacturing method of the display panel provided by an embodiment of the present disclosure, the materials for forming the reflection adjustment layer 5 are sprayed to the printing area by using a nozzle. The materials may be resin composition materials including dye and resin.

In one embodiment, a plurality of independent reflection adjustment layers may be formed by this process. In a direction perpendicular to a plane of the substrate, one reflection adjustment layer overlaps with one light-emitting element. After the materials are ejected, under the action of surface tension, its upper surface will show an arc shape, and then the surface of the finally formed reflection adjustment layer 5 far away from the substrate 1 is arched towards a direction away from the substrate 1.

Inkjet printing may be used to directly form a film layer with a specific pattern, and without using a mask. Therefore, when the reflection adjustment layer 5 is formed by the inkjet printing process, one more masking process may be omitted, so that only two masking processes are used in the process of the filter structure and the light extraction structure, saving four masking processes, and further reducing the production cost of the display panel to a greater extent.

In a feasible implementation manner, the reflection adjustment layer 5 also includes resin materials and high refractive index particles. The process of forming the reflection adjustment layer 5 includes: performing a surface treatment on the high refractive index particles to make the surface of the high refractive index particles have functional groups that may react with resin; mixing the treated high refractive index particles, the dye, the photoinitiators and the resin; and placing them at least in the first opening 7 and the second opening 8, and irradiating the resin with ultraviolet light to make the functional groups on the surface of the high refractive index particles react with the resin by grafting.

When the reflection adjustment layer 5 is formed by the photolithography process, this process of irradiating the resin with ultraviolet light may occur during the exposure process. When the reflection adjustment layer 5 is formed by the inkjet printing process, the reflection adjustment layer 5 may be irradiated with ultraviolet light after printing.

The grafting of the high refractive index particles and the resin may restrain the high refractive index particles so that they will not migrate to other film layers, reduce the risk of precipitation of high refractive index particles, and thus keep the reflection adjustment layer 5 with more stable high refractive properties.

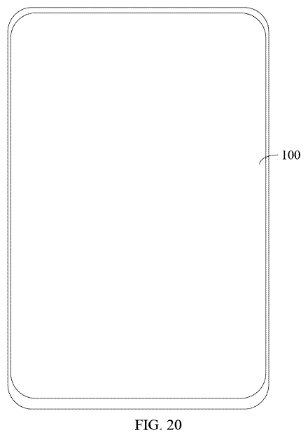

Based on the same inventive concept, an embodiment of the present disclosure also provides a display device. As shown in FIG. 20, which is a schematic structural diagram of a display device provided by an embodiment of the present disclosure, the display device includes the above display panel 100. Of course, the display device shown in FIG. 20 is only for illustrative purposes. The display device may be any electronic device with a display function, such as a mobile phone, a tablet computer, a notebook computer, an e-book reader or a television.

The above are only preferred embodiments of the present disclosure and are not intended to limit the present disclosure. Any modifications, equivalent replacements, improvements, etc. made within the spirit and principles of the present disclosure should be included within the protection scope of the present disclosure.

Finally, it should be noted that the above embodiments are only used to illustrate the technical solutions of the present disclosure, not to limit them. Although the present disclosure has been described in detail with reference to the foregoing embodiments, those skilled in the art should understand that they may still modify the technical solutions described in the foregoing embodiments, or perform equivalent replacements for some or all of the technical features, and these modifications or replacements do not make the essence of the corresponding technical solutions deviate from the scope of the technical solutions of the various embodiments of the present disclosure.

What is claimed is:

1. A display panel, comprising:
a substrate;
a light-emitting device layer comprising light-emitting elements;
a light-shielding layer located on a side of the light-emitting device layer away from the substrate, wherein the light-shielding layer comprises first openings, and in a direction perpendicular to a plane of the substrate, the first openings overlap the light-emitting elements;
a low refractive index layer located on at least a side of the light-shielding layer away from the substrate, wherein the low refractive index layer comprises second openings, and the second openings expose the first openings; and
a reflection adjustment layer located at least in the first openings and the second openings, wherein the reflection adjustment layer comprises a dye, and a refractive index of the reflection adjustment layer is greater than a refractive index of the low refractive index layer.

2. The display panel according to claim 1, wherein the reflection adjustment layer also covers at least part of the low refractive index layer.

3. The display panel according to claim 1, wherein a plurality of reflection adjustment layers that are independent from each other ae provided, and in the direction perpendicular to the plane of the substrate, one reflection adjustment layer of the plurality of reflection adjustment layer at least overlaps one light-emitting element of the light-emitting elements.

4. The display panel according to claim 3, wherein
part of the reflection adjustment layer is also located on a side of the low refractive index layer away from the substrate.

5. The display panel according to claim 3, wherein
the light-emitting element, the first opening, the second opening and the reflection adjustment layer that overlap each other have a same shape.

6. The display panel according to claim 3, wherein
a surface of the reflection adjustment layer away from the substrate is arched towards a direction away from the substrate.

7. The display panel according to claim 1, wherein
a surface of the reflection adjustment layer away from the substrate is a flat surface.

8. The display panel according to claim 1, further comprising a display area, wherein the reflection adjustment layer at least covers the display area.

9. The display panel according to claim 1, wherein
the reflection adjustment layer comprises a first sub-part and a second sub-part, the first sub-part is located in a first opening of the first openings and a second opening of the second openings, and the second sub-part is connected between different first sub-parts.

10. The display panel according to claim 1, wherein a light-emitting element of the light-emitting elements comprises a light-emitting layer;
the light-emitting device layer also comprises a pixel definition layer, the pixel definition layer comprises a fourth opening, and the light-emitting layer is located in the fourth opening; and in the direction perpendicular to the plane of the substrate, the fourth opening is located in a corresponding first opening, and a gap is formed between an edge of the fourth opening and an edge of the first opening;
wherein for the first opening and fourth opening that overlap each other, along a first direction, a distance between the edge of the first opening and the edge of the fourth opening is greater than or equal to H×Ctgβ,
wherein the first direction is parallel to the plane of the substrate, H is a distance between the light-shielding layer and the light-emitting layer along a second direction, the second direction is perpendicular to the plane of the substrate, β is a first included angle of the fourth opening, and the first included angle is an angle between a side wall of the fourth opening and a surface connected to the side wall and close to the substrate.

11. The display panel according to claim 10, wherein
the light-emitting elements comprise a first light-emitting element and a second light-emitting element, and the first light-emitting element and the second light-emitting element are configured to emit light of different colors;
wherein a first included angle of the fourth opening corresponding to the first light-emitting element is different from a first included angle of the fourth opening corresponding to the second light-emitting element.

12. The display panel according to claim 1, wherein
in the direction perpendicular to the plane of the substrate, the first opening is located in the second opening, and along a first direction parallel to the plane of the substrate, a gap is formed between an edge of the second opening and an edge of the first opening.

13. The display panel according to claim 12, wherein
along the first direction, a distance between the edge of the second opening and the edge of the first opening is less than or equal to THK1×Ctgα, wherein THK1 is a thickness of the light-shielding layer in the direction perpendicular to the plane of the substrate, and α is an angle between a side wall of the first opening and a surface connected to the side wall and close to the substrate.

14. The display panel according to claim 12, wherein
an angle between a side wall of the first opening and a surface connected to the side wall of the first opening and close to a side of the substrate is smaller than or equal to an angle between a side wall of the second opening and a surface connected to the side wall of the second opening and close to the substrate.

15. The display panel according to claim 1, wherein the low refractive index layer is also located on a side wall of the first opening.

16. The display panel according to claim 1, further comprising a high refractive index layer, wherein
the high refractive index layer is located on a side of the reflection adjustment layer away from the substrate and covers the low refractive index layer, and
a refractive index of the high refractive index layer is greater than the refractive index of the reflection adjustment layer.

17. The display panel according to claim 1, wherein the reflection adjustment layer also comprises a high refractive index resin material.

18. The display panel according to claim 1, wherein the reflection adjustment layer also comprises a resin material and a high refractive index particle.

19. The display panel according to claim 18, wherein in the reflection adjustment layer, at least part of the high refractive index particle is grafted with resin.

20. The display panel according to claim 19, wherein
the high refractive index particle comprises at least one of zirconium oxide, titanium oxide, zirconium oxide, hafnium oxide, tantalum oxide, tungsten oxide, niobium oxide, cerium oxide, lead oxide or zinc oxide, and
the resin comprises at least one of acrylic resin, epoxy resin or polyurethane resin.

21. The display panel according to claim 19, wherein
the reflection adjustment layer comprises a first sub-adjustment layer and a second sub-adjustment layer, and the first sub-adjustment layer is located on a side of the second sub-adjustment layer away from the substrate; and
wherein a grafting rate of the first sub-adjustment layer is greater than a grafting rate of the second sub-adjustment layer.

22. The display panel according to claim 1, wherein
the reflection adjustment layer comprises a first sub-adjustment layer and a second sub-adjustment layer, and the first sub-adjustment layer is located on a side of the second sub-adjustment layer away from the substrate; and
a curing rate of the first sub-adjustment layer is different from a curing rate of the second sub-adjustment layer.

23. The display panel according to claim 22, wherein the curing rate of the first sub-adjustment layer is greater than that of the second sub-adjustment layer.

24. The display panel according to claim 22, wherein the curing rate of the first sub-adjustment layer is smaller than the curing rate of the second sub-adjustment layer.

25. A method for manufacturing a display panel, comprising:
forming a light-emitting device layer comprising a plurality of light-emitting elements on a substrate;
forming a light-shielding layer on a side of the light-emitting device layer away from the substrate, wherein the light-shielding layer comprises a plurality of first openings, and in a direction perpendicular to a plane of the substrate, the first openings overlap the light-emitting elements;
forming a low refractive index layer on the light-shielding layer, wherein the low refractive index layer comprises a plurality of second openings, and the second openings expose the first openings; and
forming a reflection adjustment layer located at least in the first openings and the second openings, wherein the reflection adjustment layer comprises a dye, and a refractive index of the reflection adjustment layer is greater than a refractive index of the low refractive index layer.

26. The method according to claim 25, wherein
the forming the reflection adjustment layer comprises:
forming the reflection adjustment layer by photolithography.

27. The method according to claim 25, wherein the forming the reflection adjustment layer comprises:
forming the reflection adjustment layer by inkjet printing.

28. The method according to claim 25, wherein
the reflection adjustment layer also comprises a resin material and a high refractive index particle; and
the forming the reflection adjustment layer comprises:
performing a surface treatment on the high refractive index particle to cause a surface of the high refractive index particle to have functional groups that are capable of reacting with a resin; and
mixing the treated high refractive index particle, the dye, a photoinitiator and the resin, and placing at least in the first openings and the second openings, and irradiating the resin with ultraviolet light such that the functional groups on the surface of the high refractive index particle and the resin are subjected to grafting reaction.

29. A display device, comprising a display panel, wherein the display panel comprises:
a substrate;
a light-emitting device layer comprising light-emitting elements;
a light-shielding layer located on a side of the light-emitting device layer away from the substrate, wherein the light-shielding layer comprises first openings, and in a direction perpendicular to a plane of the substrate, the first openings overlap the light-emitting elements;
a low refractive index layer located on at least a side of the light-shielding layer away from the substrate, wherein the low refractive index layer comprises second openings, and the second openings expose the first openings; and
a reflection adjustment layer located at least in the first openings and the second openings, wherein the reflection adjustment layer comprises a dye, and a refractive index of the reflection adjustment layer is greater than a refractive index of the low refractive index layer.
